(19) United States
(12) Patent Application Publication
(10) Pub. No.: US 2014/0078688 A1
(43) Pub. Date: Mar. 20, 2014

(54) SWITCH CIRCUIT FOR SERIAL ADVANCED TECHNOLOGY ATTACHMENT CONNECTOR

(71) Applicants: HONG FU JIN PRECISION INDUSTRY (SHENZHEN) CO., L, Shenzhen (CN); HON HAI PRECISION INDUSTRY CO., LTD., New Taipei (TW)

(72) Inventors: LEI LIU, Shenzhen (CN); GUO-YI CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/706,431

(22) Filed: Dec. 6, 2012

(30) Foreign Application Priority Data
Sep. 18, 2012 (CN) 2012103458563

(51) Int. Cl. H05K 1/11

(52) U.S. Cl. CPC H05K 1/11
USPC 361/748

(57) ABSTRACT

A switch circuit is connected to a serial advanced technology attachment (SATA) connector on a motherboard. The switch circuit includes a switch unit. The switch unit connects a last pin of the SATA connector to either a power supply on the motherboard or a ground pin of the motherboard.

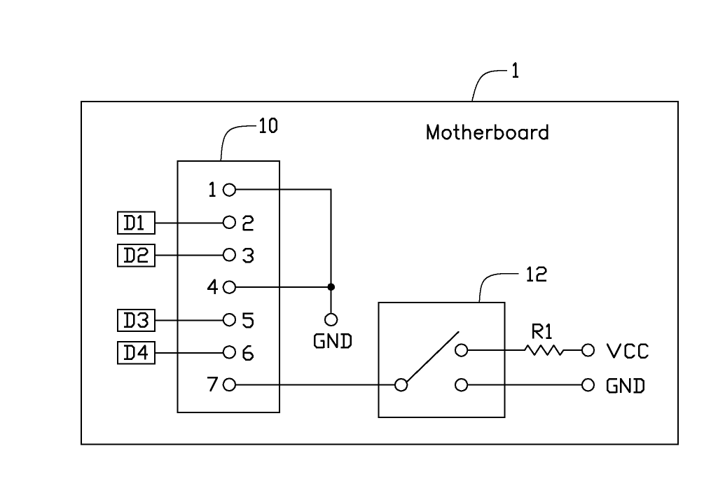

### BACKGROUND

1. Technical Field

The present disclosure relates to a circuit for switching a serial advanced technology attachment (SATA) connector.

2. Description of Related Art

A serial advanced technology attachment disk on-module (SATADOM) includes a connector with seven pins. The seventh pin of the connector is a power pin, so the SATADOM does not need an external power supply. However, a corresponding pin of a current SATA connector on a motherboard is a ground pin, so the SATADOM cannot be mounted on the motherboard with the current SATA connector. This is an inconvenience.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the view.

The FIGURE is a circuit diagram of an exemplary embodiment of a switch circuit connected to a serial advanced technology attachment connector on a motherboard.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

The FIGURE shows an embodiment of a switch circuit. The switch circuit is connected to a serial advanced technology attachment (SATA) connector 10 on a motherboard 1. Using the switch circuit, either a SATA hard disk drive (HDD) or a serial advanced technology attachment disk on-module (SATADOM) can be connected to the SATA connector 10. The SATA connector 10 includes first to seventh pins 1-7. The first pin 1, the fourth pin 4, and the seventh pin 7 are ground pins. The second pin 2 and the third pin 3 are transmitting pins. The fifth pin 5 and the sixth pin 6 are receiving pins. The first pin 1 and the fourth pin 4 of the SATA connector 10 are connected to a ground pin GND of the motherboard 1. The second pin 2, the third pin 3, the fifth pin 5, and the sixth pin 6 of the SATA connector 10 are respectively connected to data pins D1-D4 of the motherboard 1. When a SATA HDD is connected to the SATA connector 10, the SATA HDD can communicate with other elements (not shown) on the motherboard 1.

The switch circuit includes a switch unit 12 and a resistor R1. In the embodiment, the switch unit 12 is a single-pole double-throw (SPDT) switch. A pole of the SPDT switch is connected to the seventh pin 7 (namely the last pin) of the SATA connector 10. A first throw of the SPDT switch is connected to a power supply VCC on the motherboard 1 through the resistor R1. A second throw of the SPDT switch is connected to the ground pin GND of the motherboard.

When the SATA HDD is connected to the SATA connector 10, the pole of the switch unit 12 is operated to be connected to the second throw of the switch unit 12. In this state, the seventh pin 7 of the SATA connector 10 is grounded. As a result, when the SATA HDD is connected to an external power supply, the SATA HDD can communicate with other elements on the motherboard 1. When the SATADOM is connected to the SATA connector 10, the pole of the switch unit 12 is operated to be connected to the first throw of the switch unit 12. In this state, the seventh pin 7 of the SATA connector 10 is connected to the power supply VCC on the motherboard 1. As a result, the SATADOM can receive power from the motherboard 1, and communicate with the other elements on the motherboard 1.

The foregoing description of the exemplary embodiments of the disclosure has been presented only for the purposes of illustration and description and is not intended to be exhaustive or to limit the disclosure to the precise forms disclosed. Many modifications and variations are possible in light of disclosure above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A switch circuit connected to a serial advanced technology attachment (SATA) connector on a motherboard, the switch circuit comprising a switch unit, wherein the switch unit connects a last pin of the SATA connector to either a power supply on the motherboard or a ground pin of the motherboard.

2. The switch circuit of claim 1, wherein the switch unit is a single-pole double-throw (SPDT) switch, a pole of the SPDT switch is connected to the ground pin of the SATA connector, a first throw of the SPDT switch is connected to the power supply on the motherboard, a second throw of the SPDT switch is connected to the ground pin of the motherboard.

3. The switch circuit of claim 1, further comprising a resistor connected between the first throw of the SPDT switch and the power pin of the motherboard.
